(19) United States
(12) Patent Application Publication
(10) Pub. No.: US 2018/0067156 A1
(43) Pub. Date: Mar. 8, 2018

(54) ELECTROSTATIC DISCHARGE TESTING SYSTEM AND METHODS

(71) Applicants: Roger Watkins, Pleasanton, CA (US); Evan Grund, San Jose, CA (US)

(72) Inventors: Roger Watkins, Pleasanton, CA (US); Evan Grund, San Jose, CA (US)

(21) Appl. No.: 15/692,625

(22) Filed: Aug. 31, 2017

Related U.S. Application Data
(60) Provisional application No. 62/384,058, filed on Sep. 6, 2016.

(51) Int. Cl. G01R 31/00; G01R 29/12; G01R 31/28

(52) U.S. Cl. CPC G01R 31/002; G01R 31/2887; G01R 31/2879; G01R 29/12

(57) ABSTRACT

Systems and methods of applying repeatable stress pulses to an integrated circuit device under test using the charged device model (CDM) test is provided. The CDM spark conduction using discharge pin implemented in sections allows the spark environment to be controlled increasing the stress reproducibility and ability to apply the CDM test to devices with fine pitch terminals.

### CLAIM OF PRIORITY

This application claims priority to U.S. Provisional Patent Application Ser. No. 62/384,056, filed on Sep. 6, 2016, the entirety of which is incorporated herein by reference.

### BACKGROUND OF THE INVENTION

The present invention relates to electrical circuit testing, and more specifically to systems and methods for stress testing of electronic assemblies, integrated circuits, and micro-electro-mechanical devices for electrostatic discharge (ESD) sensitivity using the charged device model (CDM).

Electronics are used extensively today from computers to cell phones and increasingly in cars and homes. The trend of miniaturization has produced integrated circuits (ICs) and similar micro-devices in increasingly smaller packages with pins, pads, solder balls, or other types of electrical terminals for circuit connections with small spacing. During the manufacturing, transporting, assembling, installing and using of electronic parts, their terminals can experience anomalous inputs or electrical transients on their terminals from many sources that can cause undesired ESD stresses inducing damage or even destruction and failure. Integrated circuits are generally designed to withstand some amount of these electrostatic discharges without damage or malfunction, and stress testing to determine ESD sensitivities is widely used. One such method commonly used to determine robustness to transients is the charged device model (CDM) for evaluating sensitivity to electrostatic discharges (ESD). CDM is widely accepted as a model of real world ESD events that frequently damage ICs when an electrically charged IC is quickly discharged through one of its terminals.

CDM test equipment and methods are described in standards published by electronic industry standards bodies such as JEDEC and the Electrostatic Discharge Association (ESDA). Both organizations, among others, have standards for field-induced CDM (FICDM) testing that describe placing the packaged IC device under test (DUT) upon a field charge plate with its terminals facing upward, and having a ground plate with a pin, which becomes a discharge probe, positioned above the DUT. An electric field (E field) is produced between the field charge plate and ground plate with voltage application, and then the discharge probe pin approaches an IC terminal causing a spark between the pin and terminal. The current of the spark is a short, intense transient stress current flowing through the terminal and distributed through the IC as allowed by the capacitive coupling between the integrated circuit and the charge and ground plates. This is a standard test for ICs and similar parts, such as micro-electro-mechanical systems, but using a spark discharge to produce a quantifiable ESD test has limitations due to variations of spark currents.

Unlike the repeatable current conduction of a wire, an electrical spark doesn't have a highly consistence resistance to the current flow from one spark to the next spark. The unstable resistance of sparks gives rise to large variations in measured results from CDM testing.

Electrical spark conduction can be effected by many conditions including gas temperature, pressure, and constituents such as ambient moisture content and air flow, ambient radiation including light, electrical and magnetic fields, spark gap length (and rate of change of length) and shape of gap terminals and surface contaminations on the terminals. Controlling all these many environmental, mechanical and electrical conditions is difficult and results in large test reproducibility problems. Miniaturization of electronic parts has made the spacing of terminals small enough that sparks may not reach the desired terminal but can couple to a neighboring terminal. Therefore, there is a need to improve the reproducibility of CDM ESD testing by reducing the spark discharge inconsistencies.

### SUMMARY OF THE INVENTION

The present invention to provides reproducible current discharges resulting in stress consistency and repeatability for charged device model (CDM) electrostatic discharge (ESD) testing. This invention divides a discharge probe into two sections thereby allowing the lower section to first contact the desired terminal of the charged device under test (DUT). The gap between the two sections of the discharge probe is then reduced until the spark discharge occurs between the segments of the discharge pin. The gap between discharge pin sections is enclosed in a controlled environment to produce repeatable sparks and the section ends that form the spark gap are shaped and constructed for best spark reproducibility. Because the spark does not occur at the DUT terminal the discharge pin lower section can be sized and shaped to make low resistance contacts that are insensitive to the shape and surface conditions of the DUT terminal. Furthermore, the pre-spark contact to the DUT pin guarantees stressing the proper pin even when DUT terminals are tightly spaced or inconsistently formed.

Broadly stated, the present invention comprises a test system comprising: top and bottom electrical plates positioned on opposite sides and electrically isolated from a device under test, the plates being individually voltage controlled relative to a ground reference; a discharge probe having two sections, a lower section that is mounted to and extends through said top plate and is electrically isolated therefrom, said lower section having an upper sparking surface end extending above said top plate and a lower probe portion extending below said top plate, and an upper section mounted to a grounded support positioned above said top plate having a sparking surface end extending out from the grounded support towards the upper sparking end of said lower section; a first mechanism to cause the lower probe portion of said lower section of said discharge probe to be controllably brought into electrical contact with a selected terminal of said device under test; and a second mechanism to cause the separation between the upper sparking surface end of said lower section and the sparking surface end of said upper section to be controllably reduced to a distance where an electrical discharge is caused to occur across the gap between the upper sparking surface end of said lower section and the sparking surface end of said upper section, such that current is conducted between the device under test and the ground reference.

In another embodiment of the present invention, in a system having two electrical plates and a discharge probe having an upper and a lower section wherein said lower section extends through, but is isolated from, a first one of said electrical plates and wherein said a lower section includes an upper sparking surface end extending above said first plate and a lower probe portion extending below said first plate, and an upper section mounted to a grounded support positioned above said first plate having a sparking surface end extending out from the grounded support towards the upper sparking end of said lower section, a method for testing a device comprising: positioning the device to be tested between, but electrically isolated from, said two electrical plates; causing the lower probe portion of said lower section of said discharge probe to be brought into electrical contact with a selected terminal of said device under test; selectively applying a differential voltage between the electrical plates to induce differential charging of said device under test; and reducing the spacing between the upper and lower discharge probe sections until an electrical discharge occurs in the gap between the sections.

### BRIEF DESCRIPTIONS OF THE DRAWINGS

The present invention can be better understood with reference to the following drawings. The components within the drawings are not necessarily to scale relative to each other, emphasis instead being placed upon clearly illustrating the principles of the present invention.

FIG. 1 is a diagram of a prior art CDM test system.

FIG. 2 is an idealized discharge waveform example of CDM current that might be impressed to flow through a terminal of a device under test.

FIG. 3 is a diagram of a CDM system showing components of the current invention using a field induced charging method.

FIG. 4 is a flow chart illustrating the charging and discharging ofa DUT according to the present invention as shown in FIG. 3.

FIG. 5 is a diagram of a CDM system showing components of the current invention using a contact charging method, and also showing current discharge waveform recording components.

FIG. 6 is a flow chart illustrating the charging and discharging of a DUT according to the present invention as shown in FIG. 5.

FIG. 7(a) is a diagram of a CDM system showing an embodiment of the current invention using a sliding mechanism in a first position, and FIG. 7(b) is a diagram the CDM system of FIG. 7(s) in a second position.

### DETAILED DESCRIPTION OF THE DRAWINGS

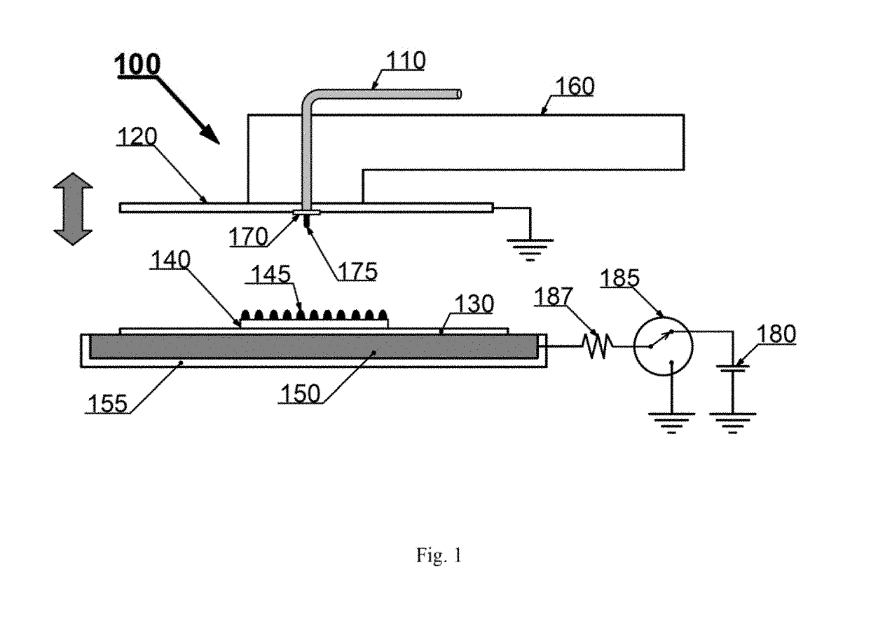

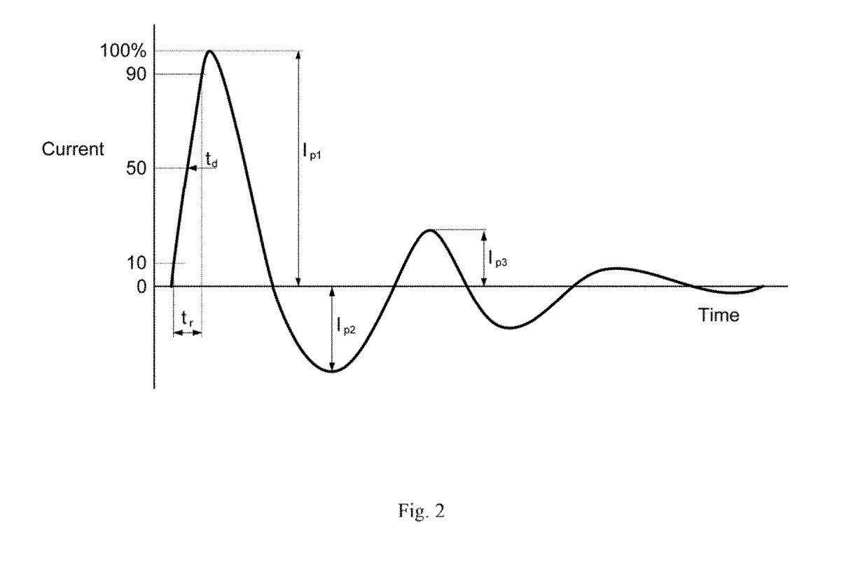

The impact of the invention can be most easily appreciated when compared with the shortcomings of the known technology. FIG. 1 depicts a schematic and simplified system diagram of an ESD tester as they are routinely employed by known technology to test semiconductor products from various technologies according to the requirements of the Charge Device Model (CDM) standard procedures. The device under test (DUT) 140 is placed on an insulating layer 130 with its terminals pointing upward. The DUT is normally electrically neutral at the beginning of the test, and is inductively charged by its internal charge being redistributed within the DUT in response to an external electric field (E field) produced by a differential voltage between the top ground plate 120 and a field charging plate 150. The high voltage power supply 180 is typically capable of supplying from 125 V to 1000 V at low currents, and when its adjustable voltage is selected and its output is connected by relay 185 and current limiting charging resistor 187, then its voltage will be imparted to the field charging plate 150 and an E field equal to that of the selected high voltage power supply voltage will be developed between the field charging plate 150 and the top ground plate 120. A pogo pin grounding discharge probe 175 is connected to the top ground plate 120 via a 1-ohm current sensing resister 170. The pogo pin probe 175 is held close to ground potential by current sensing resistor 170. The top ground plate and pogo pin probe, as an assembly, is moved by support arm 160 to vertically approach a terminal 145 on DUT 140. During this approaching motion, when the pogo pin probe 175 is sufficiently close to the DUT terminal 145, the air between pogo pin probe 175 and DUT terminal 145 will no longer be able to isolate them electrically and an electrical discharge spark will form between them. The current that flows through the air spark between the pogo pin probe 175 and the DUT terminal 145 is ideally shown in FIG. 2. The DUT current can be monitored for stress level verification by measuring the voltage across the sense resistor 170 as it changes with time using a coaxial cable 110 to transmit the signal from the resistor to a recording oscilloscope (not shown).

FIG. 2 depicts the exponentially damped oscillating current resulting from the under-damped inductor-resistor-capacitor (LRC) resonant circuit formed of the DUT 140, being inductively charged relative to ground and capacitively coupled to both ground plate 120 and field charging plate 150, the resistance and inductance of the air spark between the probe 175 and DUT terminal 145, the pogo pin discharge probe 175, current sense resistor 170, and the top ground plate 120. The resonant circuit L is the inductance of the spark path and pogo pin probe 175 and other stray inductances. The resonant circuit C is net capacitive effects of the capacitance of the DUT 140 inside its protective package and the charge plate 150 and the capacitance between DUT 140 and the top ground plate 120, and to a lesser extent the capacitance between the field charging plate 150 and the top ground plate 120. The R of the resonant circuit is 1-ohm current sense resistor 170 plus the larger and more dominate series resistance of the spark.

As is known by those familiar with CDM testing theory, the current peak amplitude and damping time are largely influenced by the spark resistance, and this spark resistance is affected by the ambient air temperature, atmospheric pressure, air currents, and air component composition, especially humidity. Furthermore, the spark resistance is also affected by the E field intensity and field shape when the spark occurs, which in turn is affected by the spacing between the bottom tip of the pogo pin probe 175, the shape of the bottom tip of the pogo pin probe 175 and DUT terminal 145, the surface conditions (including contaminations) of the pogo pin probe 175 and the DUT terminal 145, the speed of approach controlled by support arm 160, and the distance between top ground plate 120 and the DUT 140 at the moment of sparking (which depends upon the discharge pin 175 length and the voltage from the high voltage power supply 180 and the air conditions). The spark intensity also varies as a function of time during the spark as the spark forms and later dissipates; and like lightning strikes, no two sparks are identical. It can now be understood that the spark resistance has a large variation and is thereby a limitation in the repeatability of the discharge currents from pulse-to-pulse. Prior art methods have been employed to reduce discharge current pulse variations, such as enclosing the entire system 100 in a box filled with forced clean dry air (CDA) or nitrogen gas (N₂). While helpful, these measures also require special equipment and operational compromises such as CDA or N₂ purge delays between loading a new DUT and the testing initiation.

Variations in spark can sometimes be seen by the existence of “runt pulses” which have smaller than typical amplitudes. Runt pulses are especially a problem at both low and high voltage extremes.

Spark consistency is also compromised by the surface conditions of the DUT terminal 145 and pogo pin probe end 175. Contaminants such as moisture condensation, residue from manufacturing, and debris from handling can coat DUT terminals 145 and are transferred to the pogo pin 175 when these two contact each other during normal operation. The alignment of the discharge pin probe 175 to the DUT terminal 145 can be off by a small amount as alignment is typically done by the operator and limited by the mechanical motions. Alignment is also most critical with parts that have solder balls or other terminals with a fine pitch (now as small as 0.35 mm center-to-center). While it would seem that a sharp pointed lower end of the pogo pin probe 175 would be best, it has been demonstrated by published experiment that a sharp point focuses the E field and produces sparking at a larger gap distance, resulting in longer sparks with increasing possible spark jumping to a different DUT terminal than the one intended. Thus, the discharge pin probes are normally half spherical rounded and are often larger than the DUT terminals.

CDM testing is based on producing a standardized electrical discharge with a spark to the pins/balls/terminals of an IC or similar component to determine the level of such ESD stress that can be withstood without DUT damage. The present invention moves the spark from between the DUT ball/pin the grounding discharge probe at the bottom of the discharge probe head assembly to inside the probe head assembly between two pins. The division of the discharge probe into sections allows the spark to occur in a controlled environment where the spark is reproducible. The lower pin section is kept short as to not materially affect the inductance and other electrical parameters of the two section discharge probe when compared to the prior art single section pin probe.

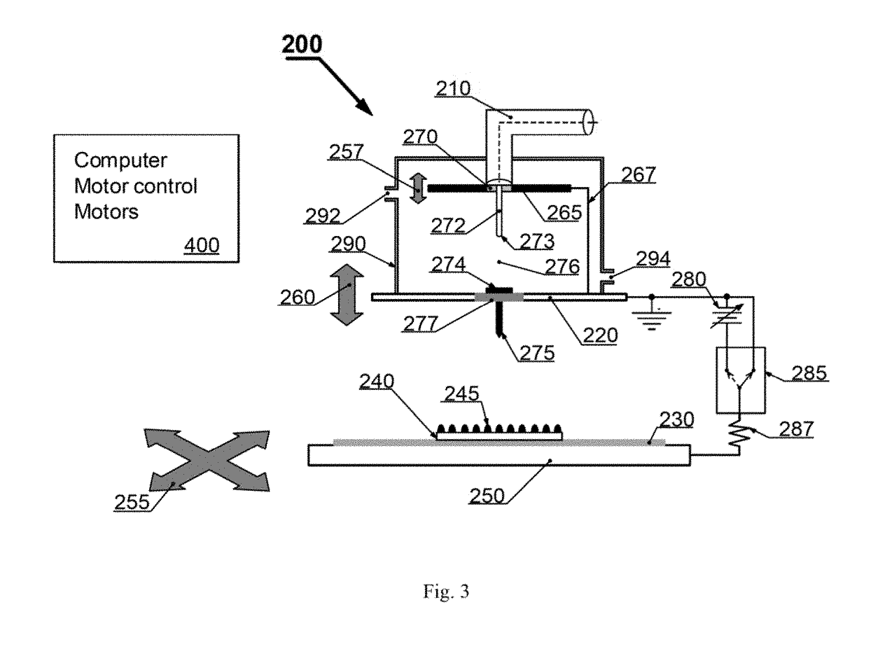

FIG. 3 shows a system 200 that embodies the present invention. The objects, features and advantages of the present invention will no doubt become apparent to those skilled in the art after reading the following description of the preferred embodiments that are illustrated in FIGS. 3-7. In the following description, numerous specific details are provided, such as the identification of various system components, to provide a thorough understanding of embodiments of the invention. One skilled in the art will recognize, however, that the invention can be practiced without one or more of the specific details, or with other methods, components, materials, etc. In still other instances, well-known structures, materials, or operations are not shown or described in detail to avoid obscuring aspects of various embodiments of the invention. Reference throughout this specification to “one embodiment” or “an embodiment” means that a particular feature, structure, or characteristic described in connection with the embodiment is included in at least one embodiment of the present invention. Thus, the appearance of the phrases “in one embodiment” or “in an embodiment” in various places throughout this specification are not necessarily all referring to the same embodiment. Furthermore, the particular features, structures, or characteristics may be combined in any suitable manner in one or more embodiments.

FIG. 3 depicts a system for CDM ESD testing using a field-induced charging method. The device under test (DUT) 240 is placed on an insulating layer 230 with its terminals pointing upward. The DUT, even though initially electrically neutral, can be differentially charged by induction by being within an electric field (E field) produced by a differential voltage between the top ground plate 220 and a field charging plate 250. The high voltage power supply 280 has an adjustable voltage and its output is connected by relay 285 and current limiting charging resistor 287 so that its voltage will be imparted to the field charging plate 250 and an E field equal to that of the selected high voltage power supply voltage will be developed between the field charging plate 250 and the top ground plate 220. A lower section grounding discharge probe 275 extends through the top ground plate 220 and is electrically isolated from the top ground plate 220 by insulating ring 277. Ground plate 220 and upper grounded support 265 are electrically connected by 267 which may be comprised of sliding contacts, braided cable, the chamber 290 walls, or other conductors, or a series or parallel combination of conductors. An upper section grounding probe 272 is held by grounded support 265 and is electrically connected to the support and thereby to the system reference ground through a current sensing resistance 270. The stress current flowing through the DUT will also flow through the sense resistor 270 as it is in series with DUT, being conducted through discharge pin sections 272 and 275. The voltage across the parallel resistances of 270 and coaxial cable 210 impedance (a 50-ohm cable is used in this embodiment) is determined by the DUT current as can be calculated by the well-known Ohm's Law. The coaxial cable 210 is used to conduct the voltage signal which is a scaled replica of the DUT current to an oscilloscope, or similar voltage recording system, which can record the voltage signal as a function of time. The resistance 270 is typically one ohm, and can be physically a single circular resistor or a set of resistors mounted on upper grounded support 265. A set of surface mounting resistors may form resistance 270 being placed a circle around upper discharge pin 272 with their total parallel resistance equally approximately one ohm.

The recording of the current waveform from the CDM discharge can be performed by a programmed oscilloscope, or a computer when the recorded data is transferred to it, to determine the total charge transferred to the DUT and the timing of charge transfer, and this information can be used to determine the stress level applied to the DUT and also if the stress meets the expected level or required test amount.

The relative motion of upper and lower sections of the discharge probe 272 and 275 is shown schematically at 257 and 260. In one embodiment, a computer 400 is used to separately control the position of the top ground plate 220 and the grounded support 265 in a conventional manner known in the art. Motion 260 indicates that the lower section probe 275 can be positioned along the z axis so that it contacts a desired terminal 245 on DUT 240. A desired DUT terminal 245 can be positioned in the x and y axis with respect to the lower section probe 275 by a motorized lateral positioning system 255 also preferably controlled by computer 400. Motion 257 indicates that the grounded support 265, and thus upper section probe 272, is positionable along the z axis such that upper section probe 272 can be moved towards lower section probe 275 in a controlled manner up to the point where the two probe sections are close enough to produce the desired spark discharge between the two probe sections across gap 276. A bearing assembly or similar means of providing a sliding translation may be used to allow the upper support 265 to move vertically relative to grounded plate 220, and then a motorized lowering motion 260 can cause 265 and 220 to move toward each other when lower pin 275 contacts DUT terminal 245. The upper section probe 272 and lower section probe 275 can be brought into physical contact by motion 257 to thereby establish an electrical conduction path from the DUT terminal 245 to ground through the resistance of series sense resistor 270. In the operation of this preferred embodiment a spark often occurs in gap 276 between the upper grounded probe section's tip 273 and the lower probe section's top surface 274.

The environment of the gap 276 between the ends 273 and 274 of the discharge probe sections 272 and 275 can be controlled with nitrogen or clean dry air forced through the area surrounding the gap by an enclosure with a gas inlet 292 and gas exhaust 294. The spark across the gap 276 is affected by the design of pins 272 and 275. The shape of the sparking surfaces 273 and 274 will change the electric field of gap 276 and hence the length of the gap when a spark starts. Round or flat ended pins will spark at a smaller gap than sharp points. A smaller gap is preferred as this tends to produce lower resistance sparks. The length of the probes 272 and 275 will change the circuit inductance to current flowing through the probes. Longer probes will increase the inductance and slow the current increase at the beginning of the spark. Limiting the total length of the pins to less than a centimeter is important to limit their inductance, and thereby reduce current oscillations that can form due to parasitic circuit inductances and capacitances and reflections from changing impedances along the current path to ground.

The operation of the preferred embodiment of FIG. 3 system 200 is controlled by computer 400 which includes high voltage supply 280 control circuitry, relay 285, and motion 260 and 257 control circuitry, and its implementation is well known to persons of ordinary skill in the art. The motor drivers/motors, connections of the computer 400 to relay 285, high voltage supply 280 voltage setting input, and other components, are not shown for clarity.

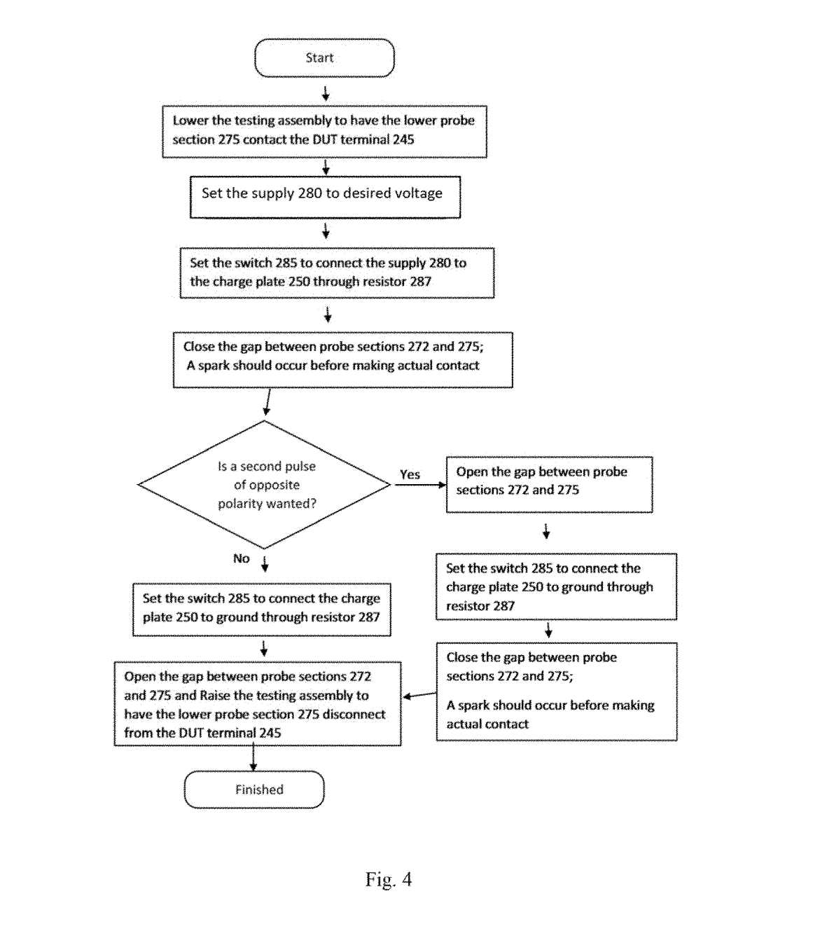

A method for CDM testing using a system such as pictured in FIG. 3 is illustrated in FIG. 4. FIG. 4 is a flow chart illustrating the charging and discharging of a DUT according to the present invention as shown in FIG. 3. As seen in FIG. 4, an electrically neutral (initially uncharged) DUT can be stressed as follows:

1) contact the DUT terminal, apply the E field, and control the spark gap environment (the order of these being unimportant):
a) the top ground plate with discharge pin probe sections and their attached assembly are moved by computer 400 as shown at 260 to have the bottom point of the lower discharge probe section 275 contact a selected terminal 245 on DUT 240; and
b) setting the relay 285 to the dotted shown position, and high voltage supply 280 voltage setting to the desired voltage, such as +500 V, the field-charging plate 250 forms the inductive E field between field-charging plate and the reference ground plate 220 which surrounds the DUT 240; and
c) dry nitrogen gas or clean dry air is introduced into the region surrounding the gap between discharge probe sections 276 through gas inlet 292 and gas exhaust 294, thus controlling the spark gap 276 gas composition, temperature and pressure,
   then
   2) produce a spark discharge, optionally with recording the event:
a) the size of the gap 276 between discharge pin sections 272 and 275 is reduced by motion 257 under control of computer 400 until the electrical potential difference between the ends of the discharge probe sections 273 and 274 are at a distance where a spark forms making a momentary electrical path across the gap 276 between discharge probe sections, and
b) in a short time period, such as a fraction of a nanosecond, current will flow from the DUT 240 from it terminal 245 through the lower discharge pin section 275 across the air spark gap 276 to the upper discharge pin section 272 through a current sense resistor 270, which is typically one ohm, through a ground path support 265 and ground path 267 to top ground plate 220, and the voltage produced by current flow through the current sense resistor 270 is connected to the inner conductor of coaxial cable 210. The outer conductor of the cable is connected to system ground. As indicated above, the coaxial cable 210 is used to conduct the voltage signal which is a scaled replica of the DUT current to a high speed oscilloscope, or similar voltage recording system, which can record the voltage signal as a function of time. As a result, the voltage signal representative of the current that flows through the DUT can be monitored on the voltage recording system.
   At the end of the above sequence of operational steps the DUT has been stressed with a charged device model current discharge of one polarity. It is normal in the evaluation of ESD sensitivity to stress a DUT with both electrical polarities. However, if a second pulse is not desired the DUT should be discharged by steps of 3).
   3) DUT is discharged by:
a) motion 257 continues to reduce the gap length of gap 276 after the spark discharge occurs to bring the two discharge probe sections into direct contact with the ends 273 and 274 touching, which essentially connects the DUT to electrical ground.
b) set the relay 285 to the solid line position to have plate 250 brought to ground potential and removing the E field that was applied to the DUT 240. This will cause the charge of the ESD simulated pulse to be conducted way slowly t ground.
c) when the DUT has been fully discharged, the motion of 257 is reversed by the computer 400 and the two sections of the discharge probe are separated, isolating the DUT from the connection to ground, and bringing the upper discharge pin support assembly 270 to its upper resting position.
   The above preferred embodiment method may be extended with a second discharge of the opposite polarity by the following method. The DUT is no longer electrically neutral after the above set of steps are completed; with the DUT now having been charged by the amount of current needed to balance the applied E field. If a second pulse of opposite polarity is desired the following steps beginning with 4) below will replace the step of 3) above.
   With the DUT precharged from the above method, or possibly by another charging method known in the art, a further CDM test method can be conducted to stress the charged DUT in the opposite polarity by approximately the same magnitude by
   4) DUT is fully charged (as the discharge pulse may not have been completely balanced the applied E field induced charging):
a) the motion 257 continues to reduce the gap length of gap 276 after the spark discharge occurs to bring the two discharge probe sections into direct contact with the ends 273 and 274 touching, which essentially connects the DUT to electrical ground which insures that the total current conducted through the DUT has fully balanced the induced potentials of the E field, and then
b) the motion of 257 is reversed by the computer 400 and the two sections of the discharge probe are separated, isolating the DUT from the connection to ground, and bringing the upper discharge pin support assembly 270 to its upper resting position, and
c) switching relay 285 to the position shown by a solid line thereby connecting the field charging plate 250 to system ground through resistor 287.
   5) contacting the DUT terminal without an E field and controlling the spark gap environment as follows (the order of these steps being unimportant):
a) the discharge assembly is, or has already been, positioned by motion 260 to have the bottom point of the lower discharge probe section 275 contact the selected terminal 245 on the precharged DUT 240 as position by motion system 255 and the E field between field-charging plate 250 and the reference ground plate 220 which surrounds the DUT 240 has been set to zero by grounding the field charge plate 250 through the resistor 287 and relay 285 which is in the position by the solid line; and
b) dry nitrogen gas or clean dry air is introduced into the region surrounding the gap between discharge probe sections 276 through gas inlet 292 and gas exhaust 294, thus controlling the spark gap 276 gas composition, temperature and pressure;
   then
   6) produce a spark discharge, optionally with recording the event:
a) the size of the gap 276 between discharge pin sections 272 and 275 is reduced by motion 257 under control of computer 400 until the electrical potential difference between the ends of the discharge pin sections 273 and 274 are at a distance that a spark forms making a momentary electrical path across the gap 276 between them; then
b) in a short time period, such as a fraction of a nanosecond, current will flow from the DUT 240 from it terminal 245 through the lower discharge pin section 275 across the air spark gap 276 to the upper discharge pin section 272 through a current sense resistor 270 through a ground path support 265 and ground path 267 to top ground plate 220, and the voltage produced by current flow through the current sense resistor 270 is connected to the inner conductor of coaxial cable 210, and outer conductor of the cable is connected to system ground, so a voltage signal representative of the current that flows through the DUT can be monitored on a device such as a high speed oscilloscope as ideally shown in FIG. 2 except that the vertical axis should be inverted for this polarity,
   then
   7) the DUT is fully discharged by grounding the DUT without an applied E field, and the system can be reset to the starting or standby condition:
a) the motion 257 continues after the spark discharge occurs to reduce the gap length and bring the two discharge probe sections into direct contact with the ends 273 and 274 touching which essentially connects the DUT to electrical ground thereby fully discharging the DUT bring it to electrical neutrality, and then
b) the motion of 257 is reversed by the computer 400 and the two sections of the discharge probe are separated, isolating the DUT from the connection to ground, bringing the upper discharge pin support assembly 270 to its upper resting position.

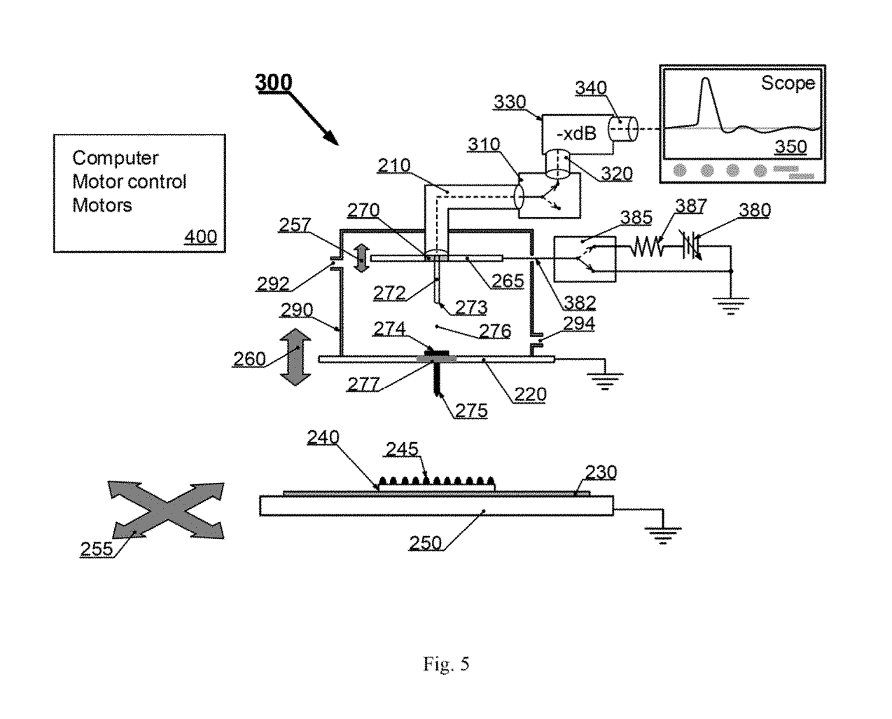

Another preferred embodiment of the present invention is shown in FIG. 5 which depicts a system for CDM ESD testing using a contact charging method.

The test system in FIG. 5 has a grounded lower support plate 250 covered by a thin insulating layer 230 upon which the DUT 240 is placed with it terminals upward. A selected DUT terminal 245 can be positioned by motorized lateral positioning system 255 to be located under the lower section of the discharge probe 275 so the DUT terminal and lower section of the discharge probe can brought into electrical contact with each other by motion 260. The lower section of the discharge probe 275 is electrically isolated by insulator 277 and held in position on the grounded upper plate 220. An upper section discharge probe 272 is movable by a motion 257 so the gap distance formed between the upper end of the lower discharge probe section 274 and the lower end of the upper discharge probe section 273 can be adjusted from a large gap to physical contact (no gap). With lower probe section 275 contacting terminal 245, an electrical connection from the high voltage power supply 380 to the DUT 240 can be completed with motion 257 bringing the upper discharge probe section 272 into contact with the lower probe section 275 and with relay 385, in its dotted arm position as shown. The DUT 240 can be charged relative to the upper and lower grounding plates 220 and 250 by current flowing from the high voltage power supply 380 through a charging current limiting resistor 387 and relay 385 and wiring 382 and support assembly 265 and current sensing resistor 270 and upper discharge probe section 272 and lower discharge probe section 275 to the DUT terminal 245. The DUT can thereby be charged to the adjustable voltage setting of the high voltage supply while the discharge current monitoring equipment (collectively 320, 330, 340 and 350) is isolated from the high voltage by relay 310 being in the dotted arm position. Once the DUT has been charged to the desired voltage and polarity, motion 257 can cause the path between the high voltage power supply 380 and the DUT terminal 245 to be disconnected.

The environment of the gap 276 between the ends 273 and 274 of the discharge probe sections 272 and 275 can be controlled with nitrogen or clean dry air forced through the area surrounding the gap by an enclosure with a gas inlet 292 and gas exhaust 294.

An upper section discharge probe 272 is held by support 265 and electrically connected to the support through a current sense resistor 270 which is typically one ohm. The upper section discharge probe can be essentially electrically connected to system ground through the support and wiring 382 and relay 385 when in its position shown by the solid arm.

The DUT 240 can be discharged in a CDM test event when the relay 385 is in the solid arm position and the motion system 257 bring the upper and lower discharge probes 272 and 275 close enough to each other that a spark will occur between their ends 273 and 274. During such a spark, the current flowing through the DUT and discharge probe sections will also flow through the sense resistor 270 on its path to ground. A voltage is developed across the parallel resistances of resistor 270 and coaxial cable 210 impedance (a 50-ohm cable is used in this embodiment) which is determined by the DUT current as can be calculated by Ohm's Law. The coaxial cable 210 is used to conduct the signal to an oscilloscope 350, or similar voltage recording system, to record the CDM discharge current as a function of time. The signal may pass through a relay 310 which is used to isolate the measurement equipment from high voltage during DUT charging, and an attenuator of predetermined value may be inserted in the signal path to reduce the signal amplitudes by a constant factor during the pulse discharge signal recording. Connecting cables, such as 320 and 340 may conduct the signal to an electrical voltage recording device such as oscilloscope.

The operation of the preferred embodiment of FIG. 5 system 300 is preferably controlled in a conventional manner by computer 400 which includes high voltage supply control, relay and motion control circuitry. The connections of the computer 400 to relay, high voltage supply voltage setting input, motor drivers/motors, and some of these components themselves, are not shown for clarity.

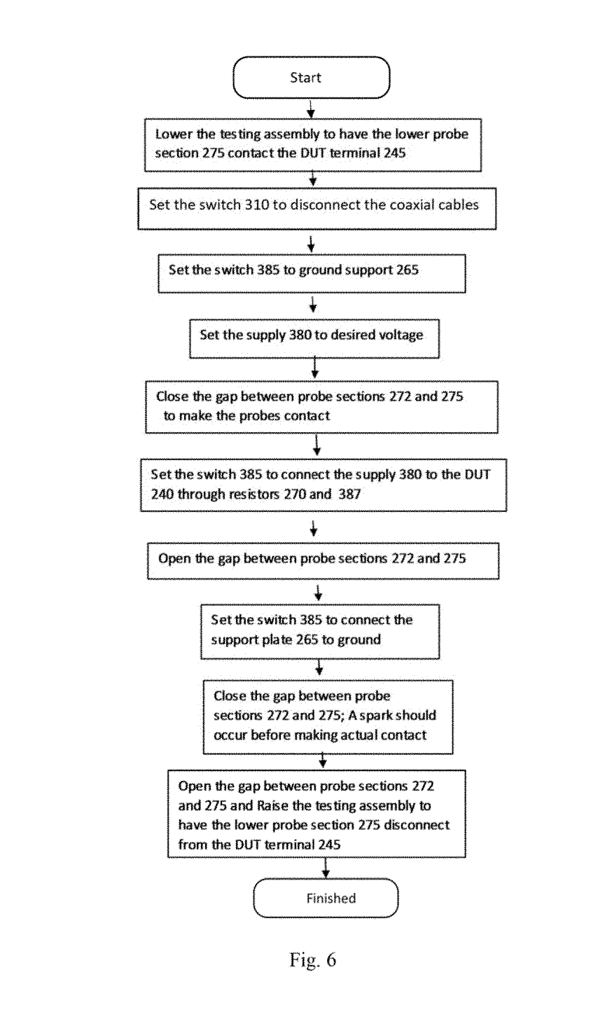

A testing method can be understood with reference to FIG. 6. FIG. 6 is a flow chart illustrating the charging and discharging of a DUT according to the present invention as shown in FIG. 5.

FIG. 6 depicts a method for CDM ESD testing using a contact charging system of FIG. 5. A CDM test operation method can be conducted to stress an electrically neutral (initially uncharged) DUT as follows:

1) contact the DUT terminal and slowly charge the DUT:
a) the device under test (DUT) 240 is placed on an insulating layer 230 with its terminals pointing upward.
b) the grounded lower support plate 250 is positioned along the x,y axes by motion 255 to place the desired DUT terminal 245 under the discharge probe lower section 275, and
c) the upper assembly with top ground plate and discharge probe sections, and their attached assembly are moved along the z axis by motion 260 to have the bottom point of the lower discharge probe section 275 contact a selected terminal 245 on DUT 240; and
d) setting the relays 310 and 385 to their dotted shown positions, and high voltage supply 380 voltage setting to the desired voltage, so that the high voltage supply will charge the DUT 240 to the voltage of the high voltage supply with current flowing through current limiting resistor 387, relay 385 wiring 382 support 265, sense resistor 270 and the discharge probe sections; and
   then
   2) isolate the DUT and control the spark gap environment (the order of these being unimportant):
a) the sections of the discharge pin sections 272 and 275 are separated along the z axis by motion 257 under control of computer 400 so the ends of the discharge probe sections 273 and 274 form a gap 276 of a length that the voltage of the DUT will not spark across that length and the relay 385 is then switched to the solid arm position as shown to connect the upper discharge probe section to system ground, and the relay 310 is switched to the solid arm position as shown, and
b) dry nitrogen gas or clean dry air is introduced into the region surrounding the gap between discharge probe sections 276 through gas inlet 292 and gas exhaust 294, thus controlling the spark gap 276 gas composition, temperature and pressure,
   then
   3) generate a CDM event with a spark discharge, and optional measurement:
c) the size of the gap 276 between discharge pin sections 272 and 275 is reduced by motion 257 under control of computer 400 until the ends of the discharge probe sections 273 and 274 are at a distance where the electrical potential difference between them forms a spark making a momentary electrical path across the gap 276 between discharge probe sections, and
d) in a short time period, such as a fraction of a nanosecond, current will flow from the DUT 240 from it terminal 245 through the lower discharge pin section 275 across the air spark gap 276 to the upper discharge pin section 272 through a current sense resistor 270, through a ground path support 265 and wiring 382 through relay 385 to ground; and the voltage produced by current flow through the current sense resistor 270 is connected to the inner conductor of coaxial cable 210, and outer conductor of the cable is connected to system ground, so a voltage signal representative of the current that flows through the DUT can be monitored on a device such as a high speed oscilloscope 350 after that signal passes through relay 310 and through attenuator 330,
   then
   4) fully discharge the DUT
d) the motion 257 continues to reduce the gap length 276 after the spark discharge occurs to bring the two discharge probe sections into direct contact with the ends 273 and 274 touching which essentially connects the DUT to electrical ground which insures that the total current conducted through the DUT has fully balanced the induced potentials of the E field, and then
e) the motion 257 is reversed by the computer 400 and the two sections of the discharge probe are separated, isolating the DUT from the connection to ground, and bringing the upper discharge pin support assembly 270 to its upper resting position.

At the end of the above sequence of operational steps the DUT has been stressed with a charged device model current discharge of one polarity. It is normal in the evaluation of ESD sensitivity to stress a DUT with both electrical polarities, so the above steps can be repeated with the high voltage power supply set to the opposite polarity and approximately the same magnitude.

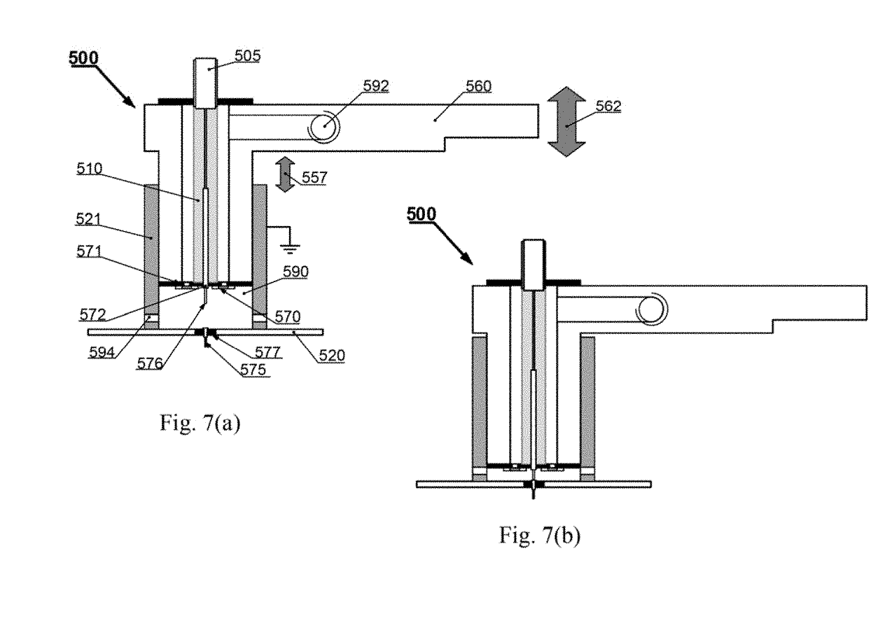

Another preferred embodiment is shown in FIGS. 7(a) and 7(b) where a support arm 560 holds the discharge assembly and provides the vertical motion 562 to raise and lower the entire discharge assembly. The vertical motion 562 of support arm 560 produces both z axis motions 257 and 260 shown in FIG. 5 with a single motion. FIG. 7(a) is a diagram of the assembly 500 in a raised position, not contacting the DUT terminal. In this raised position a support arm 560 holds the assembly 500 so the upper discharge probe section is separated from the lower discharge probe section producing a gap 576. The lower discharge probe section 575 is insulated electrically from the upper ground plate 520 by insulating ring 577. The upper discharge probe section 572 in the embodiment is a spring-loaded pogo pin which allows the two discharge pin sections to be brought into contact with each other with a small amount of overdrive. The spring contact of the pogo pin allows the motion to continue a small amount past the point of contact without damage to the contact surfaces thus insuring good contact and not requiring the high motion accuracy that would be needed to prevent contact surface damage without the spring contact. The upper discharge probe section is stabilized by support 571 which is electrically connected to system ground. The support 571 also provides a reference ground to the outer conductor of coaxial cable 510 which connects the upper discharge probe section to a high frequency cable connector 505. The upper discharge probe section and coaxial cable center conductor connected together with a resistor 570, mounted in support 571 that provides a low resistance path to ground for the current that passes through the DUT. The upper ground plate 520 is supported by housing 521 which can slide vertically relative to the upper discharge probe and its supports held by arm 560 as diagrammed by motion arrow 557. The region 590 inside the housing 521 around the gap 576 can have a gas, such as N₂, caused to flow around and through it using gas conductance path from inlet 592 through support arm 560 through the support 571 and through outlet(s) 594 in housing 521.

When the arm 560 is lowered with a conventional motion system (not shown but indicated by 562 under the control of a computer, motor controllers and motors) onto a DUT terminal (not shown) that would be positioned below the lower discharge probe section 575, the bottom tip of the lower discharge probe will contact the DUT terminal preventing the lower probe, ground plate and housing from moving further down. Subsequent additional downward motion of the arm 560 will cause motion 557 between the housing 521 and arm 560 which will cause the length of gap 576 to shorten. Continued downward motion can reduce the gap length to where a spark discharge between the discharge probe sections can occur within the environment 590 of the enclosed housing 521. This spark discharge is the desired CDM event of current flowing through the DUT pin, discharge probe sections, current sense resistor 570, support 571 and housing 521 to system ground. Subsequent additional downward motion 557 of the arm 560 will cause the housing 521 and arm 560 to further reduce the length of gap 576 until the probe sections contact each other, as shown in FIG. 5(b), resulting in a low impedance ground path from the DUT terminal to ground and a full discharge of the DUT.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A test system comprising:
top and bottom electrical plates positioned on opposite sides and electrically isolated from a device under test, the plates being individually voltage controlled relative to a ground reference;
a discharge probe having two sections, a lower section that is mounted to and extends through said top plate and is electrically isolated therefrom, said lower section having an upper sparking surface end extending above said top plate and a lower probe portion extending below said top plate, and an upper section mounted to a grounded support positioned above said top plate having a sparking surface end extending out from the grounded support towards the upper sparking end of said lower section;
a first mechanism to cause the lower probe portion of said lower section of said discharge probe to be controllably brought into electrical contact with a selected terminal of said device under test; and
a second mechanism to cause the separation between the upper sparking surface end of said lower section and the sparking surface end of said upper section to be controllably reduced to a distance where an electrical discharge is caused to occur across the gap between the upper sparking surface end of said lower section and the sparking surface end of said upper section, such that current is conducted between the device under test and the ground reference.

2. The system of claim 1 where said electrical plates are differentially charged from an electrical voltage source of selectable voltage.

3. The system of claim 1 with addition of at least one electrical switch that selectively enables the discharge probe to be-connected to a controllable voltage source rather than the ground reference, such that, when said discharge sections are brought into electrical contact, said device under test terminal receives electrical current from the voltage source.

4. The system of claim 1 further comprising a control system programmed to operate the first and second mechanisms.

5. The system of claim 1 further comprising a chamber surrounding said upper sparking surface end of said lower section and said sparking surface end of said upper section to enable the environment of the gap between said surface ends to be controlled.

6. The system of claim 5 wherein said chamber includes a first opening at one location for enabling gas to be injected into said chamber and a second opening at another location for enabling said gas to be discharged from said chamber.

7. The system of claim 6 wherein the attributes of said gas causes the temperature and/or the pressure and/or the humidity of said gap between the sections of said discharge probe to be controlled during said electrical discharge.

8. The system of claim 1 wherein the lower probe portion of said lower section of said discharge probe is shaped or pointed to make a low resistance electrical contact to terminals of said device under test having differing shapes, material compositions and surface conditions.

9. The system of claim 1 wherein the upper sparking surface end of said lower section and the sparking surface end of said upper section are shaped for maximum repeatability of the electrical discharge currents.

10. The system of claim 9 where the shape of the ends of the sections are half spherical or planar.

11. The system of claim 1 where the current through the discharge probe passes through a series resistance and the voltage signal produced across said resistance is coupled to a signal recording device.

12. The system of claim 11 where said signal recording device is an oscilloscope.

13. The system of claim 1 where said discharge probe sections are mechanically fixed along the z axis by one of two sections of a sliding translation fixture such that a single support moving in one direction holds the fixture, said sliding translation fixture enabling contact between one discharge probe section and a device under test terminal without relative motion between the discharge probe sections, and further enabling the gap length between the discharge probe sections to be reduced while maintaining contact of the lower probe portion of said lower section of said discharge probe to the selected terminal contact of the device under test.

14. In a system having two electrical plates and a discharge probe having an upper and a lower section wherein said lower section extends through, but is isolated from, a first one of said electrical plates and wherein said a lower section includes an upper sparking surface end extending above said first plate and a lower probe portion extending below said first plate, and an upper section mounted to a grounded support positioned above said first plate having a sparking surface end extending out from the grounded support towards the upper sparking end of said lower section, a method for testing a device comprising:
positioning the device to be tested between, but electrically isolated from, said two electrical plates;
causing the lower probe portion of said lower section of said discharge probe to be brought into electrical contact with a selected terminal of said device under test;
selectively applying a differential voltage between the electrical plates to induce differential charging of said device under test; and
reducing the spacing between the upper and lower discharge probe sections until an electrical discharge occurs in the gap between the sections.

15. The method of claim 14 further comprising the step of positioning a chamber around said upper sparking surface end of said lower section and said sparking surface end of said upper section to enable the environment of the gap between said surface ends to be controlled.

16. The method of claim 14 further comprising the steps of:
bringing the discharge probe sections into momentary electrical contact after said electrical discharge occurs and then separating them to a distance greater than the spacing which caused the discharge to occur;
removing the applied differential voltage between the electrical plates, thereby leaving the device under test electrically charged; and
reducing the spacing between the upper and lower discharge probe sections until an electrical discharge occurs in the gap between the sections.
